(19) United States
(12) Patent Application Publication
(10) Pub. No.: US 2016/0142050 A1
(43) Pub. Date: May 19, 2016

(54) MULTIPLE-UNIT SEMICONDUCTOR DEVICE AND METHOD FOR CONTROLLING THE SAME

(71) Applicant: SHARP KABUSHIKI KAISHA, Osaka-shi, Osaka (JP)

(72) Inventors: Naoyasu IKETANI, Osaka-shi (JP); Akio NAKAJIMA, Osaka-shi (JP); Kohsuke INNAMI, Osaka-shi (JP)

(73) Assignee: SHARP KABUSHIKI KAISHA, Osaka-shi, Osaka (JP)

(21) Appl. No.: 14/896,596

(22) PCT Filed: Jun. 6, 2014
(86) PCT No.: PCT/JP2014/065048

§ 371 Date: Dec. 7, 2015

(30) Foreign Application Priority Data
Aug. 1, 2013 (JP) 2013-160837

(51) Int. Cl. H03K 17/687

(52) U.S. Cl. CPC H03K 17/6871

(57) ABSTRACT

Provided are a multiple-unit semiconductor device that enables space savings and a method for controlling such a semiconductor device. A multiple-unit semiconductor device is brought into conduction by a Si-FET being brought into conduction first and a GaN device being brought into conduction after the Si-FET has been brought into conduction.

### TECHNICAL FIELD

The present invention relates to a multiple-unit semiconductor device in which a first field-effect transistor and a second field-effect transistor are connected in series and a method for controlling such a semiconductor device. In particular, the present invention relates to a multiple-unit semiconductor device in which a GaN (gallium nitride) device and a Si-FET are connected in a cascode arrangement and a method for controlling such a semiconductor device.

### BACKGROUND ART

Current semiconductor devices mainly use normally-off Si (silicon) field-effect transistors (so called Si-FETs). Such a normally-off field-effect transistor is a transistor which is brought into conduction when a positive voltage is applied between the gate and the source and which is brought out of conduction when no positive voltage is applied between the gate and the source.

Meanwhile, Si-FETs have been approaching their physical performance limitations. With this being the situation, research and development have been conducted with an eye toward the practical use of semiconductor devices using GaN field-effect transistors (also referred to as “GaN devices” or “GaN-FETs”) instead of Si-FETs.

GaN devices have features such as dielectric strength, low loss, high-speed switching, and high-temperature operation, and are furthermore capable of becoming higher in power. Meanwhile, GaN devices are usually normally-on FETs, and it is difficult to use GaN devices as normally-off FETs. Such a normally-on field-effect transistor, which has a negative threshold voltage, is brought out of conduction when the gate-source voltage is lower than the threshold voltage, and is brought into conduction when the gate-source voltage is higher than the threshold value.

Use of normally-on field-effect transistors in semiconductor devices presents various problems, e.g., makes it impossible to use conventional gate drive circuits. Further, normally-off GaN devices are very low in threshold voltage and therefore highly likely to malfunction. This makes it difficult to put them to practical use.

Given these circumstances, a proposal has been made to configure a normally-off multiple-unit semiconductor device such that a normally-on first field-effect transistor and a normally-off second field-effect transistor are connected in series.

PTL 1 discloses a multiple-unit semiconductor device in which a GaN device and a power MOSFET (metal-oxide semiconductor field-effect transistor) are connected in a cascode arrangement. It should be noted that PTL 1 states that it is preferable that the GaN device and the power MOSFET simultaneously receive a control signal.

PTL 2 discloses a configuration in which two switches (i.e., transistors) are connected in series (i.e., in a cascode arrangement) and in which these switches are individually controlled.

### CITATION LIST

### Patent Literature

PTL 1: U.S. Pat. No. 8,017,978 Specification (patented on Sep. 13, 2011)

PTL 2: Japanese Unexamined Patent Application Publication No. 2012-159454 (published on Aug. 23, 2012)

### SUMMARY OF INVENTION

### Technical Problem

In the multiple-unit semiconductor device disclosed in PTL 1, an attempt to simultaneously turn on and off the GaN device and the power MOSFET ends up with a high voltage being applied to the power MOSFET when the power MOSFET is turned off first. A reason why the power MOSFET is turned off first is the difference between the speed at which the GaN device is turned off by a controlling signal that turns off the multiple-unit semiconductor device and the speed at which the power MOSFET is turned off by the same signal. At the moment the multiple-unit semiconductor device is brought into conduction, there is no sufficient drop in voltage that is applied to the power MOSFET, with the result that a high voltage is applied to the power MOSFET. This requires the power MOSFET to be high in withstand voltage.

This makes it necessary to use a high-withstand-voltage power MOSFET in the multiple-unit semiconductor device disclosed in PTL 1. Actually, the withstand voltage of the power MOSFET disclosed in PTL 1 is as high as 200 V.

Note here that the GaN device is usually of a lateral structure. In this case, from the viewpoint of reliability, it is desirable that the GaN device be designed so that the lowest potential is achieved on a back surface of a substrate (i.e., so that a source potential is constituted).

Meanwhile, the power MOSFET is roughly classified as that of a lateral structure or that of a vertical structure.

A high-voltage power MOSFET of a lateral structure is large in area, and use of such a power MOSFET undesirably invites an increase in size of the multiple-unit semiconductor device.

On the other hand, a power MOSFET of a vertical structure usually has its drain electrode constituted by a back surface of a substrate. The placement of a GaN device and a power MOSFET on the same lead frame (substrate) causes a potential (source potential) of the GaN device and a potential (drain potential) of the power MOSFET to oppose each other on a back surface of the lead frame. That is, a potential that is equivalent to the drain potential of the power MOSFET is applied to a back surface of the GaN device. For this reason, use of a power MOSFET of a vertical structure undesirably degrades the reliability of the multiple-unit semiconductor device.

It should be noted that the technology disclosed in PTL 2 is only tenuously relevant to the present invention in the first place, as the two transistors connected in a cascade arrangement do not need to be a GaN device and a Si-FET (power MOSFET) at all.

The present invention has been made in view of the problems described above. It is an object of the present invention to provide a multiple-unit semiconductor device that enables space savings and a method for controlling such a semiconductor device.

### Solution to Problem

In order to solve the problems described above, a multiple-unit semiconductor device according to an aspect of the present invention is a multiple-unit semiconductor device including: a first field-effect transistor; and a second field-effect transistor connected in series to the first field-effect transistor, wherein the first field-effect transistor and the second field-effect transistor are independently controlled, and the multiple-unit semiconductor device is brought into conduction by the second field-effect transistor being brought into conduction first and the first field-effect transistor being brought into conduction after the second field-effect transistor has been brought into conduction.

In order to solve the problems described above, a method for controlling a multiple-unit semiconductor device according to an aspect of the present invention is a method for controlling a multiple-unit semiconductor device in which a first field-effect transistor and a second field-effect transistor are connected in series, the method including the steps of: independently controlling the first field-effect transistor and the second field-effect transistor; and bringing the multiple-unit semiconductor device into conduction by bringing the second field-effect transistor into conduction first and bringing the first field-effect transistor into conduction after having brought the second field-effect transistor into conduction.

### Advantageous Effects of Invention

An aspect of the present invention brings about an effect of enabling space savings.

### BRIEF DESCRIPTION OF DRAWINGS

FIG. 1 is a timing chart showing timings at which a multiple-unit semiconductor device according to an embodiment of the present invention is brought into and out of conduction.

FIG. 2 is a circuit diagram specifically showing a configuration of the multiple-unit semiconductor device according to the embodiment of the present invention.

FIG. 3 is a circuit diagram schematically showing the configuration of the multiple-unit semiconductor device according to the embodiment of the present invention.

FIG. 4 is a timing chart showing, according to another embodiment to the present invention, a comparison between a waveform of a control signal that is applied to a gate of a GaN device and a waveform of a control signal that is applied to a gate of a Si-FET.

FIG. 5 is a plan view specifically showing a configuration of a multiple-unit semiconductor device.

FIG. 6 is a side view specifically showing the configuration of the multiple-unit semiconductor device.

FIG. 7 is a plan view specifically showing a modification of the configuration of the multiple-unit semiconductor device.

### DESCRIPTION OF EMBODIMENTS

### Embodiment 1

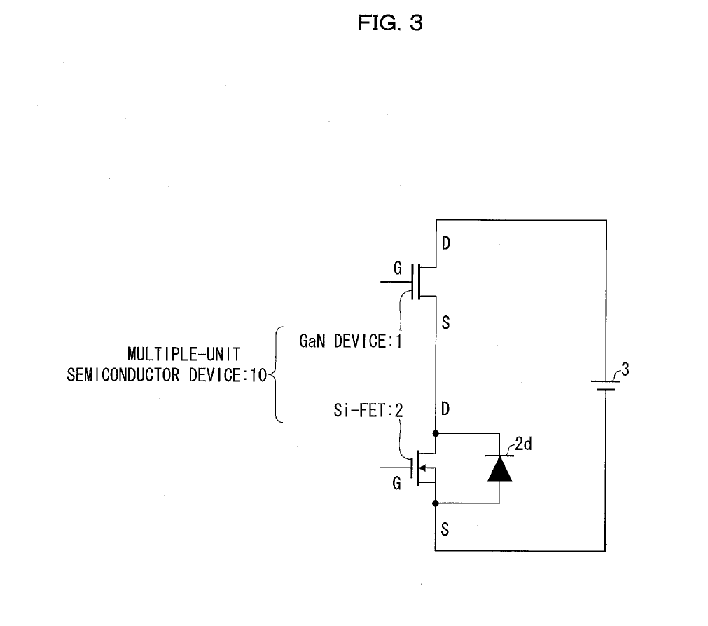

FIG. 3 is a circuit diagram schematically showing a configuration of a multiple-unit semiconductor device according to the present embodiment.

A multiple-unit semiconductor device 10 includes a GaN device (first field-effect transistor) 1 and a Si-FET (second field-effect transistor) 2. The Si-FET 2 contains a body diode 2d. The body diode 2d is parasitic on the Si-FET 2.

A drain of the GaN device 1 is connected to a high-level side of a power supply 3. A source of the GaN device 1 is connected to a drain of the Si-FET 2. A source of the Si-FET 2 is connected to a low-level side of the power supply 3. That is, the multiple-unit semiconductor device 10 is one in which the GaN device 1 and the Si-FET 2 are connected in a cascode arrangement (i.e., in series).

The GaN device 1 includes a III nitride semiconductor (compound semiconductor) such as GaN, AlGaN, or InGaN. Thanks to this, the GaN device 1 can serve as a normally-on field-effect transistor. Further, the GaN device 1 can achieve high dielectric strength, high-speed operation, high heat resistance, and low on resistance. Further, the Si-FET 2 serves as a normally-off field-effect transistor.

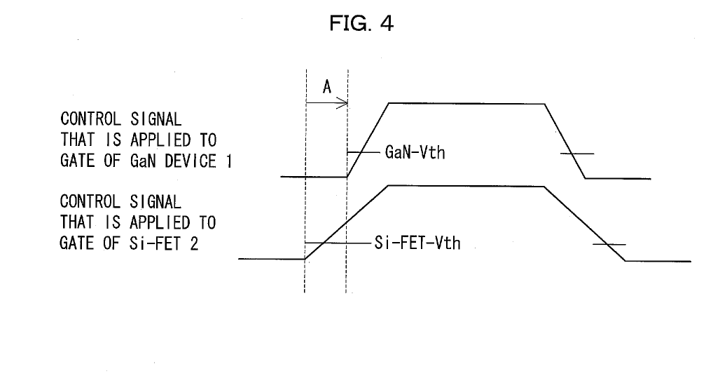

It should be noted that an operating threshold voltage (represented by GaN-Vth in FIG. 4) of the GaN device 1 may be lower than an operating threshold voltage (represented by Si-FET-Vth in FIG. 4) and may be a negative potential.

Further, it is preferable that a withstand voltage of the GaN device 1 be higher than a withstand voltage of the Si-FET 2. For example, the withstand voltage of the GaN device is 600 V. The withstand voltage of the Si-FET 2 will be described later.

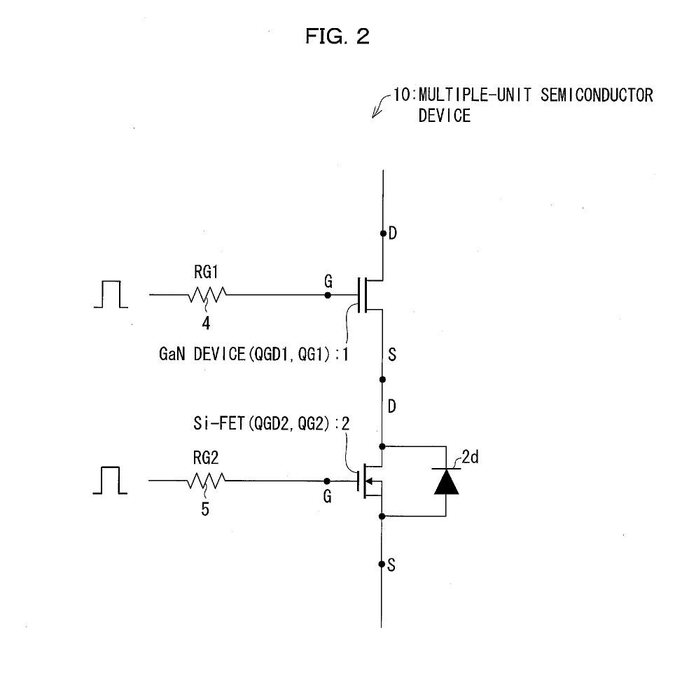

FIG. 2 is a circuit diagram specifically showing the configuration of the multiple-unit semiconductor device according to the present embodiment.

A gate of the GaN device 1 and a gate of the Si-FET 2 are controlled independently of each other. That is, in the multiple-unit semiconductor device 10, it is possible to apply different control signals to the gate of the GaN device 1 and the gate of the Si-FET 2. Thus, in the multiple-unit semiconductor device 10, it is possible to independently control timings at which the GaN devices 1 is turned on and off and timings at which the Si-FET 2 is turned on and off, and it is therefore possible to make these timings different from each other.

Further, a resistor 4 shown in FIG. 2 and located at the gate of the GaN device 1 is a gate resistor via which a current is supplied to the gate of the GaN device 1. Further, a resistor 5 shown in FIG. 2 and located at the gate of the Si-FET 2 is a gate resistor via which a current is supplied to the gate of the Si-FET 2.

As shown in FIG. 2, the characteristics of the GaN devices 1 and the Si-FET 2 are defined as follows:

RG1 is the value of gate resistance of the GaN device 1 (i.e., the resistance value of the resistor 4), and RG2 is the value of gate resistance of the Si-FET 2 (i.e., the resistance value of the resistor 5). Further, QGD1 is the value of gate-drain capacitance of the GaN device 1, and QGD2 is the value of gate-drain capacitance of the Si-FET 2. Furthermore, QG1 is the value of gate capacitance of the GaN device 1, and QG2 is the value of gate capacitance of the Si-FET 2.

Note here that when the multiple-unit semiconductor device 10 is turned on, the multiple-unit semiconductor device 10 is brought into conduction by the Si-FET 2 being brought into conduction first and the GaN device 1 being brought into conduction after the Si-FET 2 has been brought into conduction. That is, when the multiple-unit semiconductor device 10 is brought into a conductive state, control signals are applied to the gate of the GaN device 1 and the gate of the Si-FET 2 so that the Si-FET 2 is brought into conduction first and then the GaN device 1 is brought into conduction.

This configuration makes it possible to reduce the risk of a high voltage being applied to the Si-FET 2, as the GaN device 1 is not brought into conduction first. This allows the Si-FET 2 to be lower in withstand voltage. This in turn allows the Si-FET 2 to be smaller in area, thus enabling a reduction in size of the multiple-unit semiconductor device 10 (i.e., space savings).

That is, in the Si-FET 2, which is of a lateral structure, the withstand voltage of the Si-FET 2 becomes higher with increasing drain-gate distance, and becomes higher with increasing drain-source distance. Lowering the withstand voltage of the Si-FET 2 is synonymous with reducing these distances. Reducing these distances allows the Si-FET 2 (or, typically, a chip on which the Si-FET 2 is mounted) to be smaller in area.

On the other hand, when the multiple-unit semiconductor device 10 is turned off, the multiple-unit semiconductor device 10 is brought out of conduction by the GaN device being brought out of conduction first and the Si-FET 2 being brought out of conduction after the GaN device 1 has been brought out conduction. That is, when the multiple-unit semiconductor device 10 is brought into a non-conductive state, control signals are applied to the gate of the GaN device 1 and the gate of the Si-FET 2 so that the GaN device 1 is brought out of conduction first and then the Si-FET 2 is brought out of conduction.

This configuration makes it possible to reduce the risk of a high voltage being applied to the Si-FET 2, as the GaN device 1 is not brought out of conduction after the Si-FET 2 has been brought out conduction. Thus, the aforementioned mechanism enables a reduction in size of the multiple-unit semiconductor device 10 (i.e., space savings).

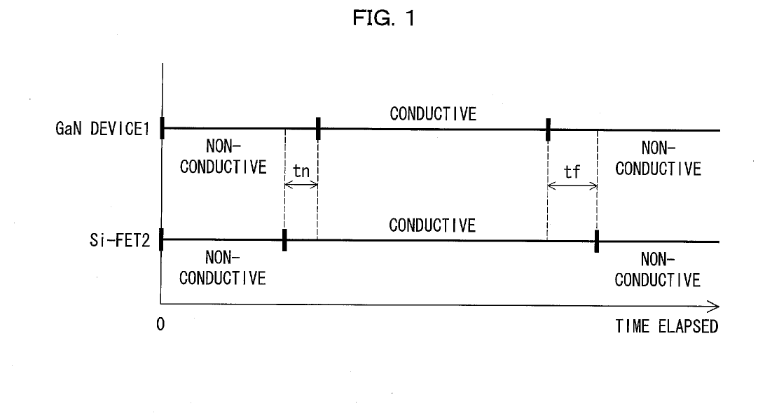

FIG. 1 shows timings at which the multiple-unit semiconductor device according to the present embodiment is brought into and out of conduction.

It should be noted that a preferred amount of time by which a timing at which the Si-FET 2 is brought into conduction precedes a timing at which the GaN device 1 is brought into conduction (i.e., how long the time to shown in FIG. 1 is set to be) varies depending on the characteristics of the GaN device 1 and the Si-FET 2. However, the GaN device 1 is brought into conduction at a timing after the Si-FET 2 has been brought into conduction and a voltage that is applied to the Si-FET 2 has become equal to or lower than the withstand voltage of the Si-FET 2. Therefore, for example when the Si-FET 2 has a withstand voltage of 30 V, it is only necessary to exercise control so that the GaN device 1 is brought into conduction after the voltage that is applied to the Si-FET 2 has become lower than 30 V.

### Embodiment 2

FIG. 4 is a timing chart showing, according to the present embodiment, a comparison between a waveform of a control signal that is applied to a gate of a GaN device and a waveform of a control signal that is applied to a gate of a Si-FET.

The following specifically describes a technique for bringing the Si-FET 2 into conduction at a timing preceding a timing at which the GaN device 1 is brought into conduction. The following also specifically describes a technique for bringing the GaN device 1 out of conduction at a timing preceding a timing at which the Si-FET 2 is brought out of conduction.

The control signal that is applied to the gate of the GaN device 1 is delayed. In so doing, for example, the control signal that is applied to the gate of the GaN device 1 starts to rise at the same timing as the control signal that is applied to the gate of the Si-FET 2 exceeds the operating threshold voltage Si-FET-Vth of the Si-FET 2. This delay time is represented by A in FIG. 4. As a technique for delaying the control signal that is applied to the gate of the GaN device 1, a well-known delay signal can be used.

Further, at this point in time, the amount of time required for rising of the control signal that is applied to the gate of the GaN device 1 is made shorter than the amount of time required for rising of the control signal that is applied to the gate of the Si-FET 2. Further, at this point in time, the amount of time required for falling of the control signal that is applied to the gate of the GaN device 1 is made shorter than the amount of time required for falling of the control signal that is applied to the gate of the Si-FET 2.

For this to happen, it is preferable that the gate resistance of the GaN device 1 and the gate resistance of the Si-FET 2 be determined so as to satisfy Mathematical Expressions (1) and (2):

RG1*QGD1<RG2*QGD2 (1)

RG1*QG1<RG2*QG2 (2)

This makes it possible to bring the Si-FET 2 into conduction at a timing preceding a timing at which the GaN device 1 is brought into conduction and to bring the GaN device 1 out of conduction at a timing preceding a timing at which the Si-FET 2 is brought out of conduction.

Further, let it be assumed that RG3 is the built-in gate resistance of the GaN device 1, VG1 is the gate drive voltage of the GaN device 1, and QGVTH1 is the gate capacitance up to the threshold voltage in the GaN device 1. Further, let it be assumed that RG4 is the built-in gate resistance of the Si-FET 2, VG2 is the gate drive voltage of the Si-FET 2, and QGVTH2 is the gate capacitance up to the threshold voltage in the Si-FET 2. In this case, it is preferable that the gate resistance of the GaN device 1 and the gate resistance of the Si-FET 2 be determined so as to satisfy Mathematical Expression (3):

(RG1+RG3)*QGVTH1/VG1<(RG2+RG4)*QGVTH2/VG2 (3)

According to this, the GaN device 1 is not brought into conduction first; therefore, no high voltage is applied to the Si-FET 2.

Alternatively, the GaN device 1 can be brought into reverse conduction by utilizing the body diode 2d during an off time. That is, by controlling the Si-FET 2 and the GaN device 1 so that the Si-FET 2 is in an off state and the GaN device 1 is in an on state, the GaN device 1 can be made to also function as a diode. In so doing, for example, even if the threshold voltage of the GaN device 1 is a negative potential, the GaN device 1 can be brought into an on state by setting the control voltage to 0 V. This makes it possible to control the turning on and turning off of the GaN device 1 in a range of a negative voltage to 0 V. As a result, even when the GaN device 1 functions as a diode, no high-voltage-side potential is required. This makes it possible to achieve a simpler power supply system.

### Embodiment 3

A multiple-unit semiconductor device according to the present embodiment is the same as each of those according to the embodiments described above, except that it uses a Si-FET 2 of a vertical structure. The Si-FET 2 has a first principal surface and a second principal surface. Provided on the first principal surface are a gate electrode having a gate potential and a drain electrode having a drain potential. Provided on the second principal surface is a source electrode having a source potential.

As described above, the GaN device 1 is of a lateral structure. The GaN device 1 has a first principal surface on which a gate electrode, a source electrode, and a drain electrode are provided and a second principal surface on which no electrodes are provided.

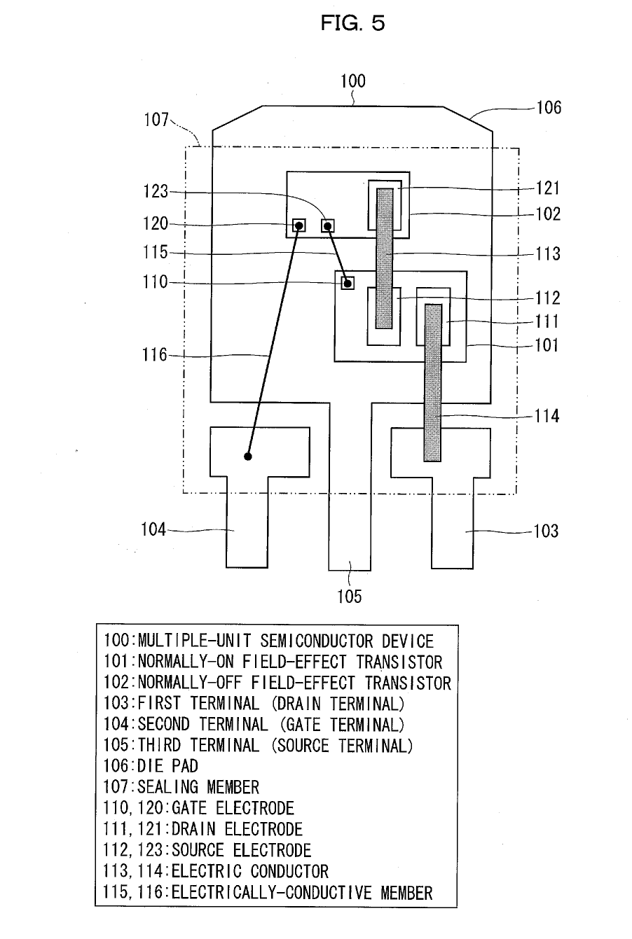

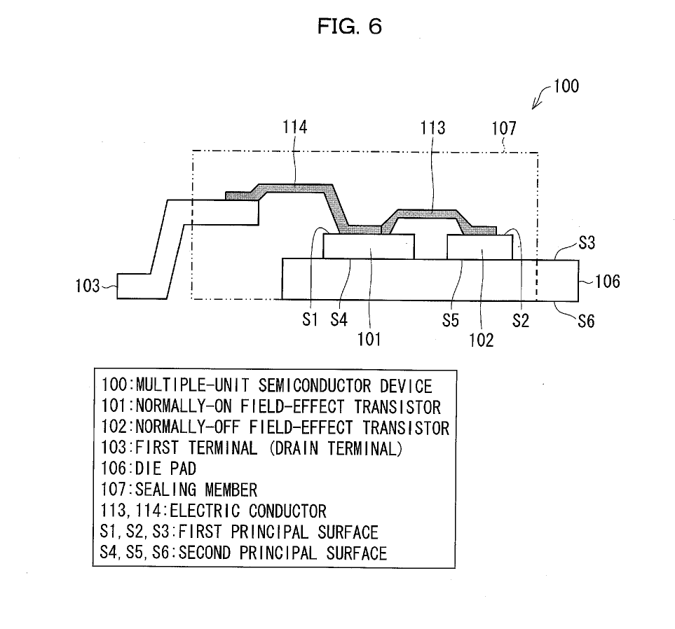

A configuration of a multiple-unit semiconductor device 100, which is a multiple-unit semiconductor device according to the present embodiment, is specifically described with reference to FIGS. 5 to 7. FIGS. 5 and 6 are a plan view and a side view, respectively, of the multiple-unit semiconductor device 100. It should be noted that the FIG. 6 omits to show a part of FIG. 5.

As shown in FIG. 5, the multiple-unit semiconductor device 100 includes a normally-on field-effect transistor 101 (hereinafter referred to simply as “transistor 101”), a normally-off field-effect transistor 102 (hereinafter referred to simply as “transistor 102”), a first terminal 103 (drain terminal), a second terminal 104 (gate terminal), a third terminal 105 (source terminal), a die pad 106, and a sealing member 107. The transistor 101, constituted for example by a GaN device 1, has a higher withstand voltage than the transistor 102 does. The transistor 102 is for example a Si-FET 2. The die pad 106 needs only be made of a material having electrical conductivity, and is not limited in other conditions. Further, the sealing member 107 is for example made of resin.

In the multiple-unit semiconductor device 100, as shown in FIGS. 5 and 6, the transistor 101 and the transistor 102 are connected in a cascode arrangement. The transistor 101 and the transistor 102 are placed on the die pad 106. Further, the transistor 101 and the transistor 102 are sealed with the sealing member 107. The die pad 106 has a lower surface a part of which also serves as a source terminal of the multiple-unit semiconductor device 100. In the following, upper and lower surfaces of the transistor 101 are referred to as a first principal surface S1 and a second principal surface S4, respectively. Upper and lower surfaces of the transistor 102 are referred to as a first principal surface S2 and a second principal surface S5, respectively. Upper and lower surfaces of the die pad 106 are referred to as a first principal surface 83 and a second principal surface S6, respectively.

As shown in FIGS. 5 and 6, a gate electrode 110, a drain electrode 111, and a source electrode 112 are placed on the first principal surface S1 of the transistor 101. A gate electrode 120 and a drain electrode 121 are placed on the first principal surface S2 of the transistor 102. Further, although not illustrated, a source electrode 122 is placed on the second principal surface S5 of the transistor 102. The source electrode 122 does not defeat the purpose of the present invention regardless of whether the whole or a part of a back surface of the transistor 102 serves as the source electrode 122.

The source electrode 112 placed on the first principal surface S1 of the transistor 101 and the drain electrode 121 placed on the first principal surface S2 of the transistor 102 are electrically connected to each other by an electric conductor 113. The drain electrode 111 placed on the first principal surface S1 of the transistor 101 and the first terminal 103 are electrically connected to each other by an electric conductor 114.

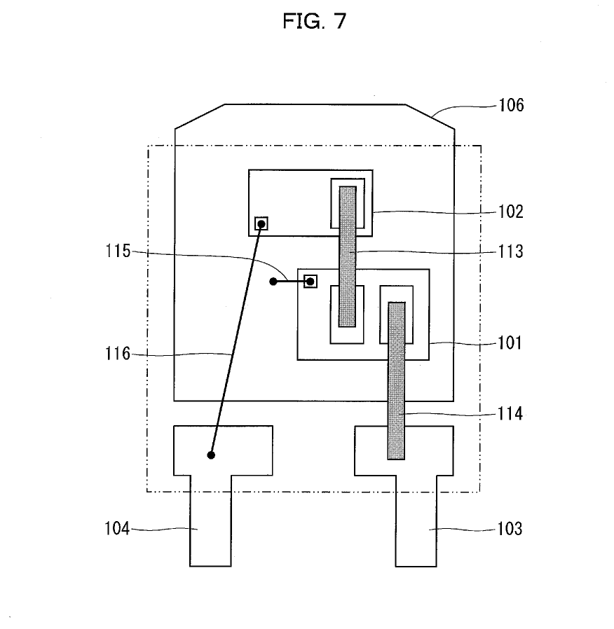

The gate electrode 120 placed on the first principal surface S2 of the transistor 102 and the second terminal 104 are electrically connected to each other by an electrically-conductive member 116. The gate electrode 110 placed on the first principal surface S1 of the transistor 101 and a source electrode 123 placed on the first principal surface S2 of the transistor 102 are electrically connected to each other by an electrically-conductive member 115. Alternatively, the gate electrode 110 may be configured to be electrically connected to the first principal surface S3 of the die pad 106 (see FIG. 7). Further, the source electrode 122 placed on the second principal surface S5 of the transistor 102 and the first principal surface S3 of the die pad 106 are electrically connected to each other.

In the multiple-unit semiconductor device 100, as shown in FIG. 6, the first principal surface S3 of the die pad 106 and the second principal surface S5 of the transistor 102 are in face-to-face contact with each other. Further, the first principal surface S3 of the die pad 106 and the second principal surface S4 of the transistor 101 are in face-to-face contact with each other.

The second principal surface S4 of the transistor 101 is die-bonded onto the first principal surface S3 of the die pad 106 with a thermally-conductive die bonding material. The thermal conductivity of the die bonding material allows heat generated in the transistor 101 to be dissipated into the die pad 106. It should be noted that since the transistor 101 and the die pad 106 do not need to be electrically connected to each other, the die bonding material does not need to have electrical conductivity. The second principal surface S5 of the transistor 102 is die-bonded onto the first principal surface S3 of the die pad 106 with solder or the like. The solder functions to both die-bond the transistor 102 to the die pad 106 and electrically connect the transistor 102 and the die pad 106 to each other. It should be noted that the solder may be replaced by an electrically-conductive paste of high die bonding performance.

In the multiple-unit semiconductor device according to the present embodiment, the GaN device 1 (transistor 101) and the Si-FET 2 (transistor 102) are placed on the same lead frame. Moreover, the second principal surface S4 of the GaN device 1 is at the same potential as a cascade source potential (i.e., a source potential of the Si-FET 2). Therefore, no high voltage such as a drain potential is applied to the GaN device 1. This allows the multiple-unit semiconductor device to achieve a high degree of reliability.

[Overview]

A multiple-unit semiconductor device according to Aspect 1 of the present invention is a multiple-unit semiconductor device including: a first field-effect transistor (GaN device 1); and a second field-effect transistor (Si-FET 2) connected in series to the first field-effect transistor, wherein the first field-effect transistor and the second field-effect transistor are independently controlled, and the multiple-unit semiconductor device is brought into conduction by the second field-effect transistor being brought into conduction first and the first field-effect transistor being brought into conduction after the second field-effect transistor has been brought into conduction.

A method for controlling a multiple-unit semiconductor device according to Aspect 8 of the present invention is a method for controlling a multiple-unit semiconductor device in which a first field-effect transistor and a second field-effect transistor are connected in series, the method including the steps of: independently controlling the first field-effect transistor and the second field-effect transistor; and bringing the multiple-unit semiconductor device into conduction by bringing the second field-effect transistor into conduction first and bringing the first field-effect transistor into conduction after having brought the second field-effect transistor into conduction.

This configuration makes it possible to reduce the risk of a high voltage being applied to the second field-effect transistor, as the first field-effect transistor is not brought into conduction first. This allows the second field-effect transistor to be lower in withstand voltage. This in turn allows the second field-effect transistor to be smaller in area, thus enabling a reduction in size of the multiple-unit semiconductor device (i.e., space savings).

In Aspect 1 above, a multiple-unit semiconductor device according to Aspect 2 of the present invention is configured such that the first field-effect transistor is a normally-on field-effect transistor and such that the second field-effect transistor is a normally-off field-effect transistor.

In Aspect 1 or 2 above, a multiple-unit semiconductor device according to Aspect 3 of the present invention is configured such that the multiple-unit semiconductor device is brought out of conduction by the first field-effect transistor being brought out of conduction first and the second field-effect transistor being brought out of conduction after the first field-effect transistor has been brought out conduction.

In Aspect 8 above, a method for controlling a multiple-unit semiconductor device according to Aspect 9 of the present invention includes the step of bringing the multiple-unit semiconductor device out conduction by bringing the first field-effect transistor out of conduction first and bringing the second field-effect transistor out conduction after having brought the first field-effect transistor out of conduction.

This configuration makes it possible to reduce the risk of a high voltage being applied to the second field-effect transistor, as the first field-effect transistor is not brought out of conduction after the second field-effect transistor has been brought out conduction. Thus, the aforementioned mechanism enables a reduction in size of the multiple-unit semiconductor device (i.e., space savings).

In any of Aspects 1 to 3 above, a multiple-unit semiconductor device according to Aspect 4 of the present invention is configured such that an operating threshold voltage of the first field-effect transistor is lower than an operating threshold voltage of the second field-effect transistor.

In Aspect 4 above, a multiple-unit semiconductor device according to Aspect 5 of the present invention is configured such that the operating threshold voltage of the first field-effect transistor is a negative voltage.

In Aspect 2 above, a multiple-unit semiconductor device according to Aspect 6 of the present invention is configured such that the second field-effect transistor has a first principal surface on which a gate electrode and a drain electrode are provided and a second principal surface on which a source electrode is provided.

The configuration makes it possible to improve the reliability of the multiple-unit semiconductor device.

In any of Aspects 1 to 6 above, a multiple-unit semiconductor device according to Aspect 7 of the present invention is configured such that a withstand voltage of the first field-effect transistor is higher than a withstand voltage of the second field-effect transistor.

In Aspect 8 or 9 above, a method for controlling a multiple-unit semiconductor device according to Aspect 10 of the present invention includes the step of determining a gate resistance of the first field-effect transistor and a gate resistance of the second field-effect transistor so as to satisfy Mathematical Expression (1):

RG1*QGD1<RG2*QGD2 (1)

where RG1 is a value of a gate resistor via which a current is supplied to a gate of the first field-effect transistor, RG2 is a value of a gate resistor via which a current is supplied to a gate of the second field-effect transistor, QGD1 is a value of gate-drain capacitance of the first field-effect transistor, and QGD2 is a value of gate-drain capacitance of the second field-effect transistor.

In Aspect 8 or 9 above, a method for controlling a multiple-unit semiconductor device according to Aspect 11 of the present invention includes the step of determining a gate resistance of the first field-effect transistor and a gate resistance of the second field-effect transistor so as to satisfy Mathematical Expression (2):

RG1*QG1<RG2*QG2 (2)

where RG1 is a value of a gate resistor via which a current is supplied to a gate of the first field-effect transistor, RG2 is a value of a gate resistor via which a current is supplied to a gate of the second field-effect transistor, QG1 is a value of gate capacitance of the first field-effect transistor, and QG2 is a value of gate capacitance of the second field-effect transistor.

The present invention is not limited to the embodiments described above, but may be altered within the scope of the claims. An embodiment based on a proper combination of technical means disclosed in different embodiments is encompassed in the technical scope of the present invention. Furthermore, a new technical features may be formed by a combination of technical means disclosed in the embodiments.

### INDUSTRIAL APPLICABILITY

The present invention is applicable to a multiple-unit semiconductor device in which a normally-on first field-effect transistor and a normally-off second field-effect transistor are connected in a cascode arrangement and a method for controlling such a semiconductor device. In particular, the present invention is applicable to a multiple-unit semiconductor device in which a GaN device and a Si-FET are connected in a cascade arrangement and a method for controlling such a semiconductor device.

### REFERENCE SIGNS LIST

1 GaN device (first field-effect transistor)
2 Si-FET (second field-effect transistor)
10 Multiple-unit semiconductor device

1. A multiple-unit semiconductor device, comprising:
a first field-effect transistor; and
a second field-effect transistor connected in series to the first field-effect transistor,
wherein the first field-effect transistor and the second field-effect transistor are independently controlled, and
the multiple-unit semiconductor device is brought into conduction by the second field-effect transistor being brought into conduction first and the first field-effect transistor being brought into conduction after the second field-effect transistor has been brought into conduction.

2. The multiple-unit semiconductor device according to claim 1, wherein the first field-effect transistor is a normally-on field-effect transistor, and
the second field-effect transistor is a normally-off field-effect transistor.

3. The multiple-unit semiconductor device according to claim 1, wherein the multiple-unit semiconductor device is brought out of conduction by the first field-effect transistor being brought out of conduction first and the second field-effect transistor being brought out of conduction after the first field-effect transistor has been brought out conduction.

4. The multiple-unit semiconductor device according to claim 1, wherein a withstand voltage of the first field-effect transistor is higher than a withstand voltage of the second field-effect transistor.

5. A method for controlling a multiple-unit semiconductor device in which a first field-effect transistor and a second field-effect transistor are connected in series, the method comprising the steps of:
independently controlling the first field-effect transistor and the second field-effect transistor; and
bringing the multiple-unit semiconductor device into conduction by bringing the second field-effect transistor into conduction first and bringing the first field-effect transistor into conduction after having brought the second field-effect transistor into conduction.
